(19) United States
(12) Patent Application Publication
(10) Pub. No.: US 2002/0044416 A1
(43) Pub. Date: Apr. 18, 2002

(54) Micro hard drive caddy

(76) Inventors: Jasper E. Harmon III, Star, ID (US); Daniel A. Gilbert, Boise, ID (US)

Correspondence Address: Joseph W. Holland, P.O. Box 1840, Boise, ID, 83701-1840, US

(21) Appl. No.: 09/909,119

(22) Filed: Jul. 18, 2001

(51) Int. Cl. H05K 5/00

(52) U.S. Cl. 361/685; 248/638

(57) ABSTRACT

A micro hard drive caddy for connecting a micro hard drive to a printed circuit board. The micro hard drive caddy may mount directly to a printed circuit board or other substrate or in the alternative may mount directly to a bus interface socket such as an IDE ribbon cable connector or a PCI slot, both located directly on the processor's main or motherboard. The micro hard drive caddy may also include a vibration isolation and dampening member preferably, although not necessarily, disposed between the interior of the frame and the exterior the micro hard drive, within the footprint of the micro hard drive frame. The micro hard drive caddy may also include a conductive connector for conductively connecting the micro hard drive to an electronic device or system. The conductive connector may include a vibration isolating conductive ribbon.

### BACKGROUND OF THE INVENTION

1. Technical Field

This invention relates generally to disk drives and more particularly to a micro hard drive caddy for connecting a micro hard drive to an electronic system or device.

2. Background

Until now, the hard disk drive size has been a limiting factor in reducing overall size of electronic devices. Miniature hard disk drives or micro hard drives have recently become available such as those manufactured by International Business Machines (IBM™) identified as the Microdrive™. The IBM® Microdrive® has three modes of access, memory, I/O or IDE. Currently, the Microdrive™ is available including 170, 340, 512 and 1024 megabytes (MB) of hard disk storage in a package the size of a compact flash memory device, which is on the order of one inch square. This product is designed as a low cost alternative to compact flash memory. While hard disk operation is slower than compact flash memory, it is less expensive and non-volatile.

There exists a need to provide a micro hard drive caddy for receiving and attaching a micro hard drive to a substrate such as a printed circuit board. Alternately, there may be advantage found in providing a micro hard drive caddy for receiving and mounting the micro hard drive directly to a bus interface socket such as the Integrated Device Electronics (IDE) ribbon cable connector or a Peripheral Component Interconnect (PCI) slot, both located directly on the processor's motherboard.

There is also concern that excessive vibration may lead to decreased micro hard drive performance. Generally speaking, disk drives, regardless of their physical size, are susceptible to problems arising from shock and vibration during handling, shipping, installation, and operation. Displacement of the hard disk or other drive component parts during operation may damage to the drive. Additionally, displacement of the hard disk or other drive component parts during operation may impede performance. This may be evidenced by a variety of performance malfunctions including increased seek, read and write access times, write inhibits and micro hard drive failures that may not be repairable including damaged disks or heads, wear on micro hard drive components, and uncorrectable data defects. Therefore, a need exists to reduce system vibration caused by any of a variety of sources.

In proposing solutions to reduction or elimination of vibration in an micro hard drive, concern must be given to the fact that most often a primary design objective, as evidenced by the choice of an micro hard drive in the first instance, is the reduction of overall device size. Therefore, in proposing such solutions for reduction or elimination of vibration in an micro hard drive there is desire to achieve this objective substantially within the footprint of the frame.

There also exists a need to provide a means for providing conductive connection of the micro hard drive to the device or system in which the micro hard drive is installed. Due to the miniature size and concealability of the micro hard drive, there is also reasonable concern that the micro hard drive may become a target for unauthorized removal and theft. Therefore, there is also a need for providing a means to secure the micro hard drive within a device in a manner that deters unauthorized removal.

### SUMMARY

The present invention is directed to a micro hard drive caddy for connecting a micro hard drive to an electronic device or system. The micro hard drive caddy includes a micro hard drive frame for supporting and retaining the micro hard drive and a conductive connector for conductively connecting the micro hard drive to an electronic device or system.

The micro hard drive frame includes a support frame portion and a retainer frame portion. The support frame portion supports the micro hard drive in position in relationship to the substrate and the drive socket. The retainer frame portion retains the micro hard drive in the support frame portion. The component parts of the frame work in conjunction to limit movement of the micro hard drive in a “Y” and a “Z” axis. In the first preferred embodiment of the invention, the component parts of the frame work in conjunction to limit movement of the micro hard drive in an “X”, a “Y” and a “Z” axis. The micro hard drive frame may be attached directly to a substrate or printed circuit board, for instance by soldering or by mechanical connection.

The micro hard drive may be removably insertable within the frame or, in the alternative, the micro hard drive may be installed semi-permanently within the frame. Removal of the micro hard drive from the frame in this instance may be achieved by use of a tool provided specifically to effect removal by authorized personnel and deter removal by unauthorized personnel.

The micro hard drive caddy also includes a conductive connector for conductively connecting the micro hard drive to an electronic device or system. In a first preferred embodiment of the invention, the conductive connector includes a drive socket conductively connected to an adapter connector. The adapter connector is conductively connectable to a board mounted conductor. The conductive connector may include a vibration isolating conductive ribbon.

An alternate preferred embodiment of the micro hard drive caddy includes a frame for supporting and retaining the micro hard drive and a conductive connector for conductively connecting the micro hard drive to an electronic device. In the alternate preferred embodiment the conductive connector includes a drive socket conductively connected to an adapter connector. The drive socket may be conductively connected to the adapter connector through a printed circuit board. In this embodiment, the adapter connector includes a bus interface socket. The drive socket and the adapter connector are conductively connected by a printed circuit board. The bus interface socket may include an Integrated Device Electronics (IDE) ribbon cable connector or a Peripheral Component Interconnect (PCI) slot. Depending upon the type of drive and type of bus it may be possible to mount multiple drives on the same adapter mount. If the drive can only operate as a master drive, only one drive can be mounted per IDE connector, limiting the number of miniature drives to two per standard motherboard, i.e. a motherboard having two IDE connectors controlled by an on-board controller. However, employing different drives, different controllers and/or different bus architectures may allow daisy chaining of more than one drive per connector.

The micro hard drive caddy may also include a vibration isolation and dampening member preferably, although not necessarily, disposed between the interior of the frame and the exterior the micro hard drive, within the footprint of the micro hard drive frame.

The micro hard drive caddy may include a micro drive ejector to facilitate removal of the disk drive from the drive mount adapter. The micro hard drive caddy may be oriented on a plane that lies substantially perpendicular to the plane of the motherboard. The orientation of the substrate and therefor the micro hard drive may be changed. For instance, in a PCI bus implementation it may be desirable to have the printed circuit board in a vertical orientation so as to not interfere with other expansion cards or slots. The micro hard drive caddy may include a voltage regulator or other electrical circuitry as desired or required for operation.

The present invention consists of the combination and arrangement of parts hereinafter more fully described, illustrated in the accompanying drawings and more particularly pointed out in the appended claims, it being understood that changes may be made in the form, size, proportions and minor details of construction without departing from the spirit or sacrificing any of the advantages of the invention.

### DESCRIPTION OF THE FIGURES

FIG. 1 is a representative perspective view of a micro hard drive caddy according to the present invention;

FIG. 2 is a representative perspective view of a micro hard drive caddy according to the present invention;

FIG. 3 is a representative top view of a micro hard drive caddy according to the present invention;

FIG. 4 is a representative top view of a micro hard drive caddy according to the present invention;

FIG. 5 is a representative perspective view of a vibration isolation and dampening member according to the present invention;

FIG. 6 is a representative exploded perspective view of a frame and a vibration isolation and dampening member according to the present invention;

FIG. 7 is a representative perspective view of a vibration isolation and dampening member according to the present invention;

FIG. 8 is a representative perspective view of a vibration isolation and dampening member according to the present invention;

FIG. 9 is a representative perspective view of a vibration isolation and dampening member according to the present invention;

FIG. 10 is a representative perspective view of a vibration isolation and dampening member according to the present invention;

FIG. 11 is a circuit schematic of a vibration isolating conductor;

FIG. 12 is a circuit schematic of circuitry according to the present invention;

FIG. 13 is a representative side view of a micro hard drive caddy including a computer bus interface socket according to one embodiment of the invention;

FIG. 14 is a representative side view of a micro hard drive caddy including a computer bus interface socket according to one embodiment of the invention;

FIG. 15 is a representative side view of a micro hard drive caddy including a computer bus interface socket according to one embodiment of the invention;

FIG. 16 is a representative side view of a micro hard drive caddy including a computer bus interface socket according to one embodiment of the invention; and

FIG. 17 is a circuit schematic of circuitry according to the present invention.

### DETAILED DESCRIPTION

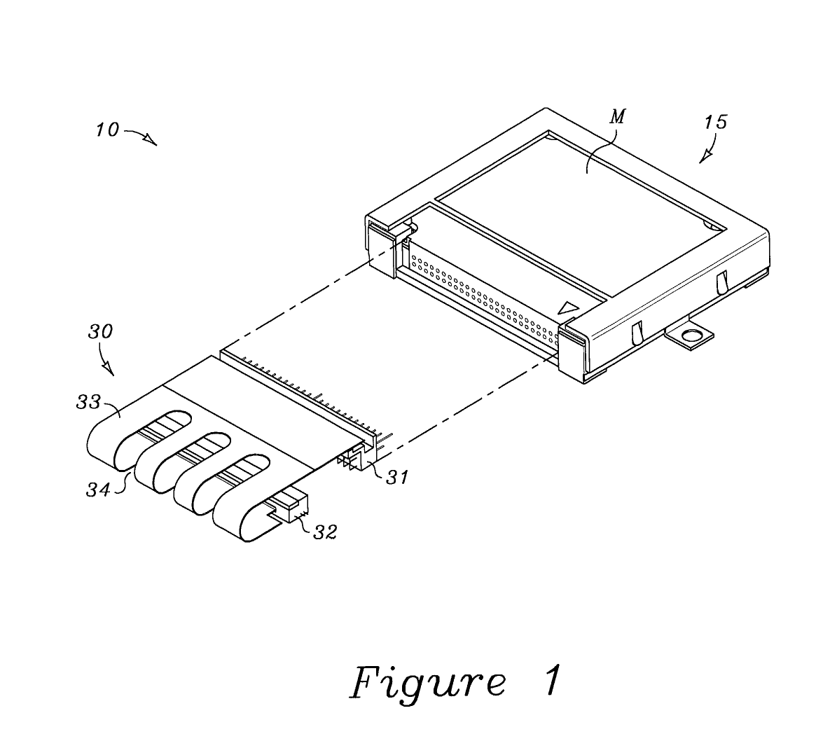

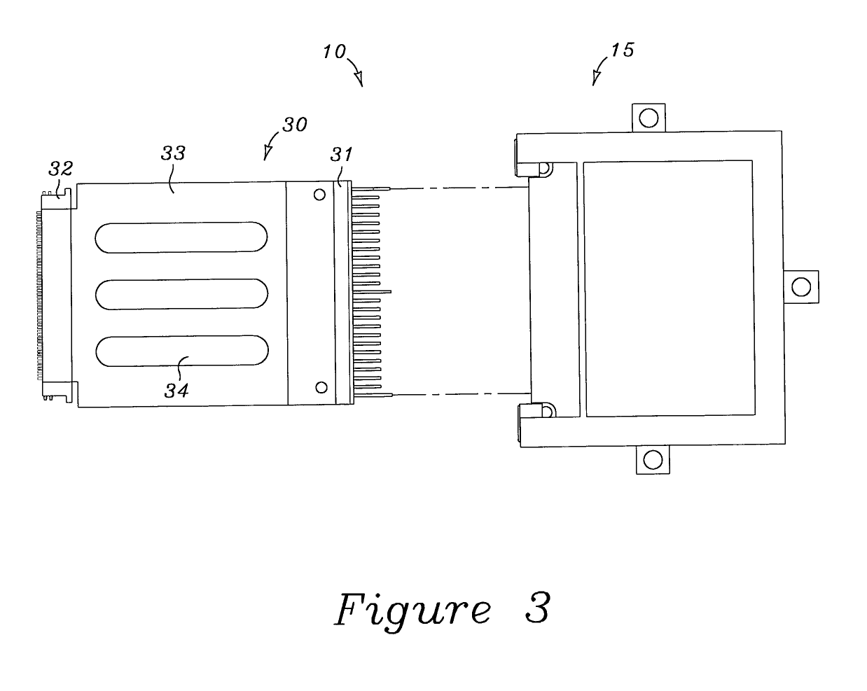

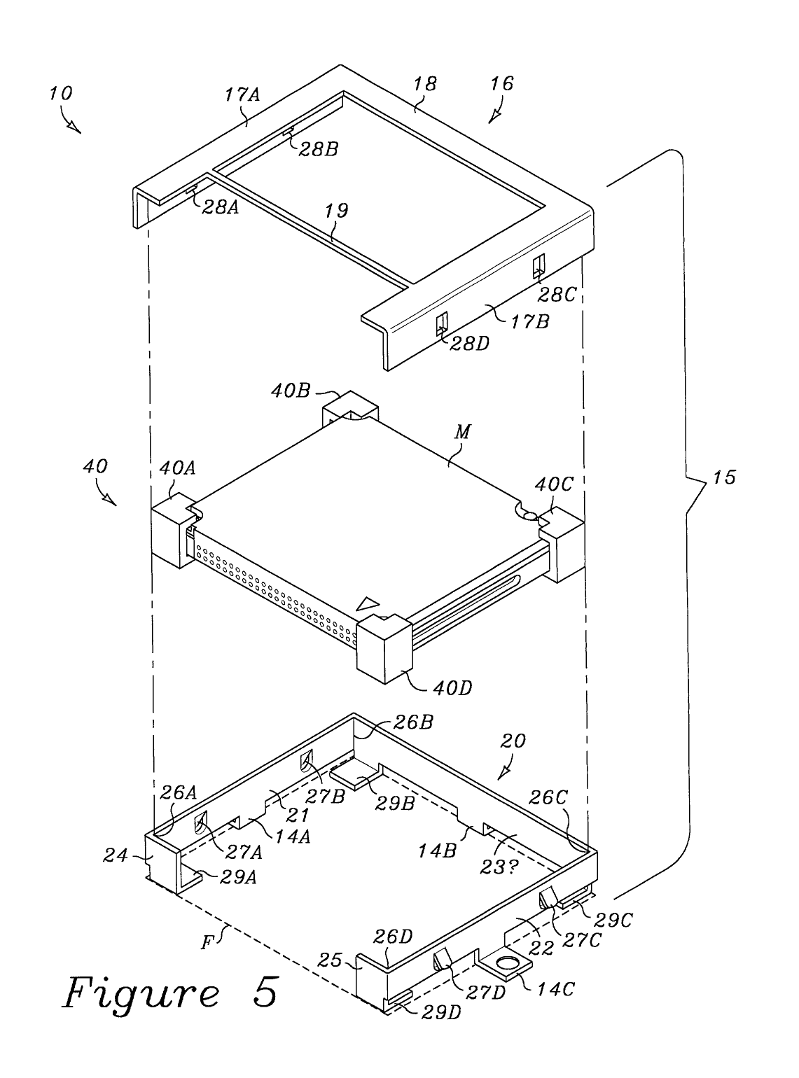

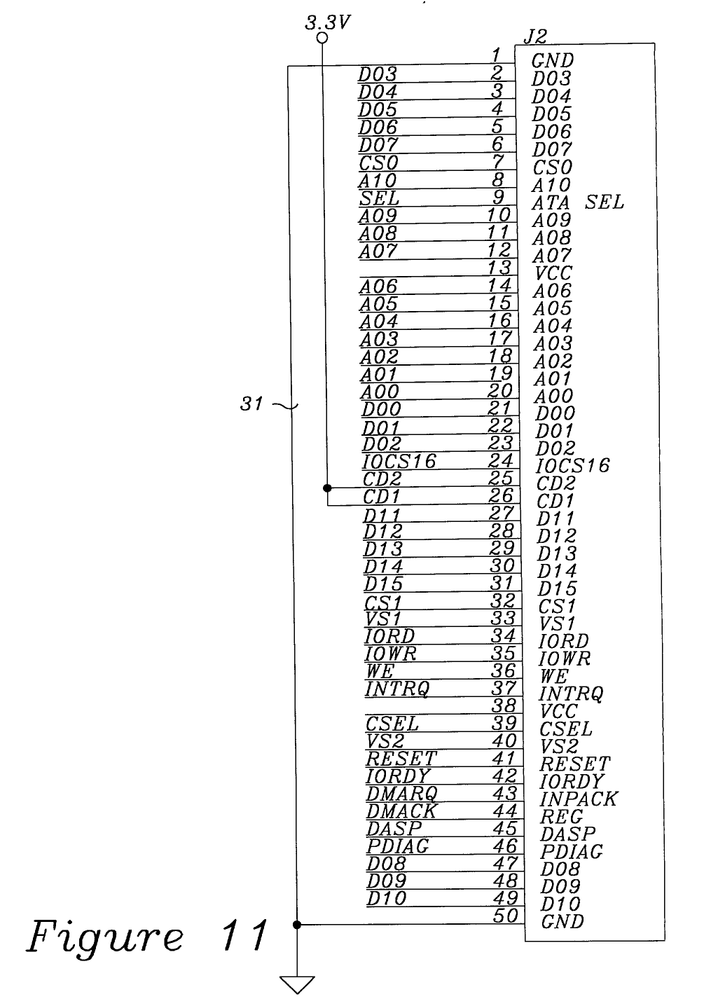

FIGS. 1 through 12 illustrate a first preferred embodiment of micro hard drive caddy 10 according to the present invention. As shown at FIGS. 1 through 4, micro hard drive caddy 10 includes frame 15, vibration isolating connector 30 and vibration isolation and dampening member 40 shown in FIGS. 5 through 10. Micro hard drive M is supported within frame 15.

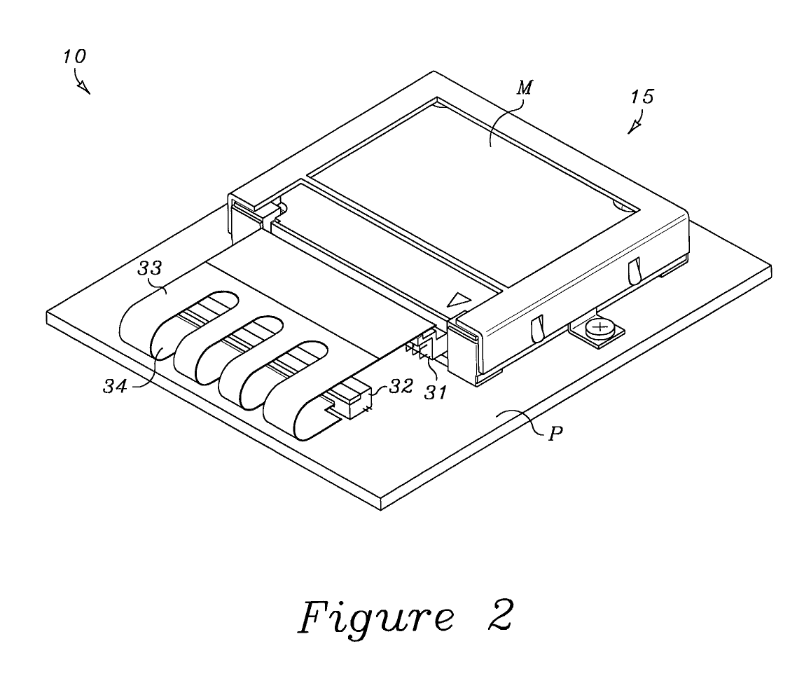

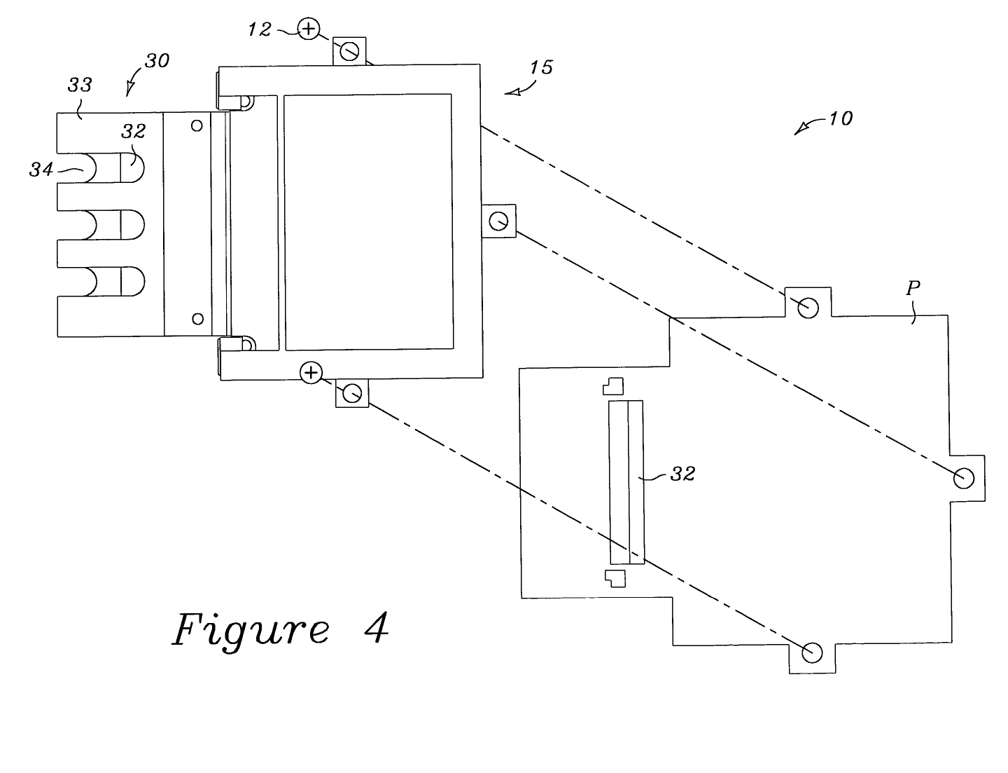

As shown in FIGS. 1 through 4, vibration isolating conductor 30 includes drive socket 31 which, in this instance is a 50 pin connector, conductively connected to a board mounted conductor, in this case, snap connector 32 by conductor ribbon 33. Snap connector 32 is connected to printed circuit board P, shown at FIGS. 2 and 4. Vibration isolating connector 30 includes cutouts 34 which permit a unique flexibility along the length of conductor ribbon 33. In compression, the ribbon deflects laterally permitting a vibration isolating function between a substrate and the micro hard drive M.

The component parts of frame 15 of the first preferred embodiment of micro hard drive caddy 10 are shown to advantage in FIG. 5. Frame 15 includes retainer frame portion 16 and support frame portion 20. Support frame portion 20 includes first side member 21 and second side member 22 connected by end member 23. First face tab 24 and second face tab 25 are attached to first side member 21 and second side member 22 at opposing corners of support frame portion 20. Support feet 29A, 29B, 29C and 29D connect to support frame portion 20 at each of the four corresponding frame corners 26A, 26B, 26C, and 26D. Support frame portion 20 with its support feet 29A, 29B, 29C and 29D supports micro hard drive M in frame 15. Tangs 27A, 27B, 27C and 27D are formed in opposing first side member 21 and second side member 22 respectively and cooperate with retainer frame portion 16 as described below.

Retainer frame portion 16 includes opposing angular edge members 17A and 17B which are interconnected by first spanning member 18 and second spanning member 19. Retainer frame portion 16 retains the micro hard drive in support frame portion 20.

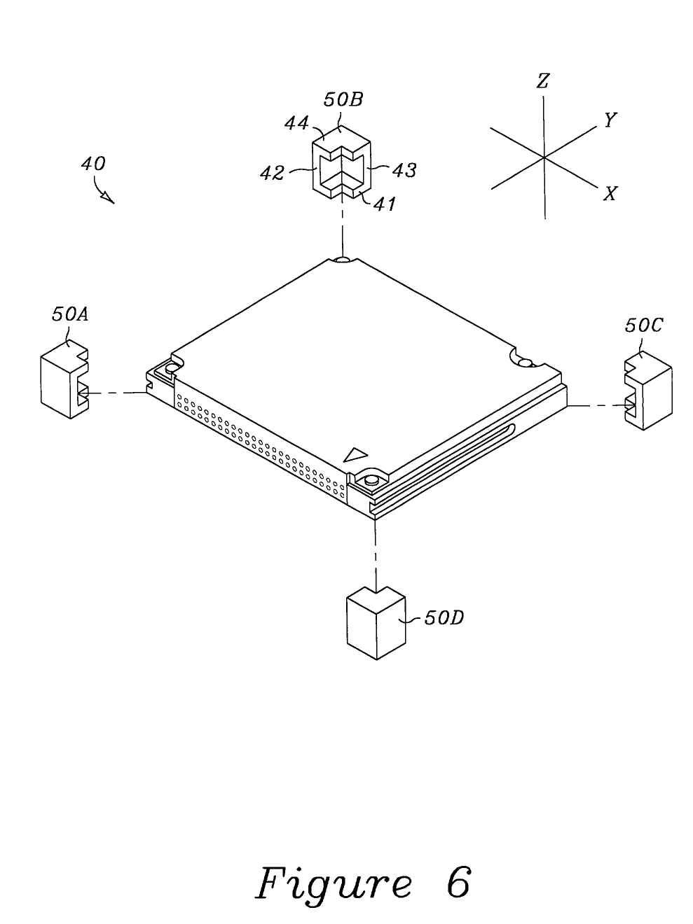

FIGS. 5 and 6 shows a first embodiment of a vibration isolation and dampening member 40 according to the present invention. Vibration isolation and dampening member 40 as shown in FIG. 6 includes dampening members 50A, 50B, 50C and 50D each individually attachable over a corner of micro hard drive M. As shown in FIG. 6, each dampening member 50A, 50B, 50C and 50D includes foot pad 41, first side pad 42, second side pad 43 and cap pad 44.

Dampening members 50A, 50B, 50C and 50D fit at each of the four corners of micro hard drive M. Micro hard drive M is supported within vibration isolation and dampening member 40 which in turn is supportable within support frame portion 20. Retainer frame portion 16 includes a close clearance fit over support frame portion 20 and tangs 27A, 27B, 27C and 27D engage with corresponding tang receivers 28A, 28B, 28C and 28D attaching retainer frame portion 16 to support frame portion 20 and providing a relatively low cost deterrent to unauthorized removal of micro hard drive M form hard drive adapter system 10. In a preferred embodiment of the invention, vibration isolation and dampening member 40 is formed of an thermoplastic rubber identified by the trademark Santoprene® furnished by the Ebbtide Polymers Corporation. Santoprene® exhibits an elongation of 450% and a modulus of elasticity, GPa, on the order of 0.001.

Drop test results employing micro hard drive caddy 10 including vibration isolation and dampening member 40 mounted to a substrate supporting micro hard drive M, wherein micro hard drive caddy 10 is dropped a vertical distance of 1 meter onto a concrete floor results in a peak force to printed circuit board P on the order of 5000-8525 g's while micro hard drive M experiences a peak force on the order of 1670-193 5g's. Similarly, drop test results employing micro hard drive caddy 10 including vibration isolation and dampening member 40 mounted to a substrate supporting micro hard drive M, wherein micro hard drive caddy 10 is dropped a vertical distance of 1 meter onto a concrete floor results in a peak force to printed circuit board P on the order of five time that experienced by micro hard drive M.

Frame 15 is sized such that dampening members 50A, 50B, 50C and 50D and micro hard drive M fit within a footprint F of frame 15 with a zero clearance between the outer faces of dampening members 50A, 50B, 50C and 50D and the corresponding inner faces of frame corners 26A, 26B, 26C, and 26D. Opposing first side member 21 and second side member 22 serve together as an X axis movement limiter, limiting movement of micro hard drive M and vibration isolation and dampening member 40 in an X axis. Similarly, end member 23 opposes first face tab 24 and second face tab 25 serve together as a Y axis movement limiter, limiting movement of micro hard drive M and vibration isolation and dampening member 40 in a Y axis. Finally, retainer frame portion 16 opposes support frame portion 20 serve together as a Z axis movement limiter, limiting movement of micro hard drive M and vibration isolation and dampening member 40 in a Z axis.

As shown, support frame portion 20 also includes ears 14A, 14B and 14C for mechanical attachment to printed circuit board P, as illustrated in FIG. 2 through 4, by fasteners 12. Alternately, ears 14A and 14B may be configured to project through a PCB for soldered attachment.

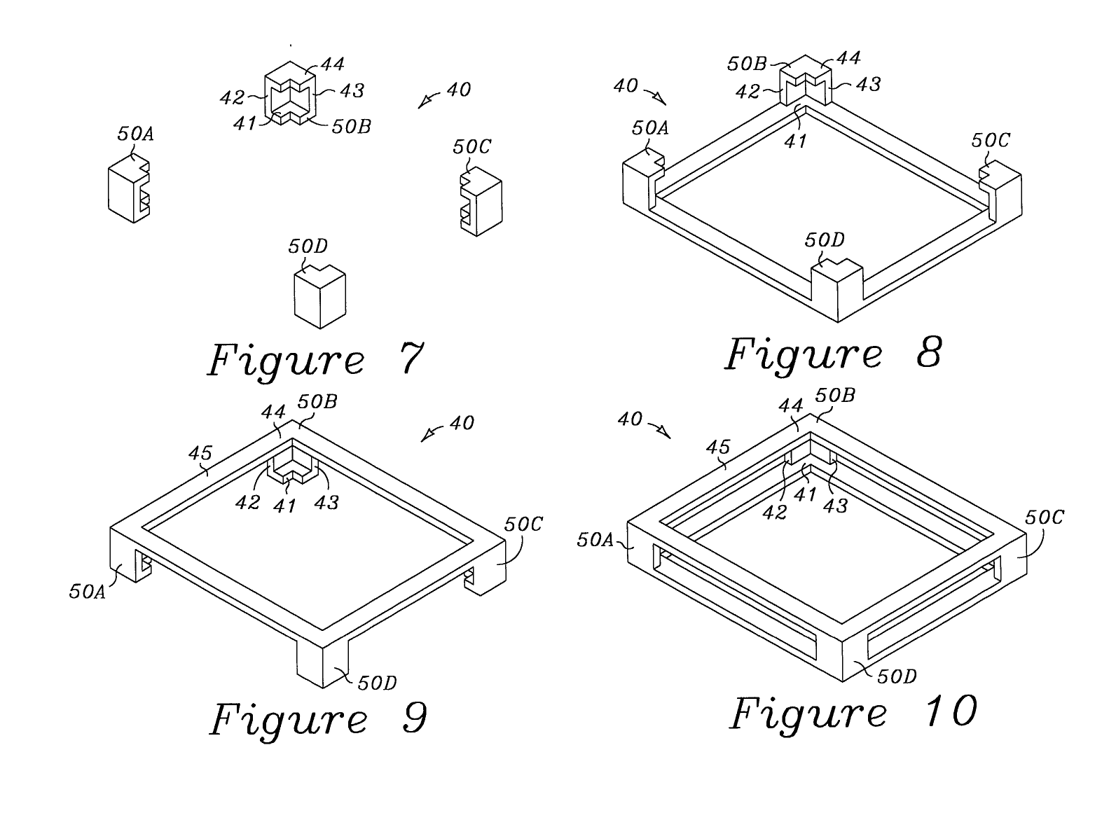

FIGS. 7 through 10 depict various embodiments of a vibration isolation and dampening member 40 according to the present invention. Vibration isolation and dampening member 40 includes dampening members 50A, 50B, 50C and 50D. Each dampening member 50A, 50B, 50C and 50D includes foot pad 41, first side pad 42, second side pad 43 and cap pad 44. In the embodiments depicted at FIGS. 8 through 10, each dampening member 50A, 50B, 50C and 50D also includes pad connector member 45 which attaches dampening members 50A, 50B, 50C and 50D one to another for ease of installation and added dampening.

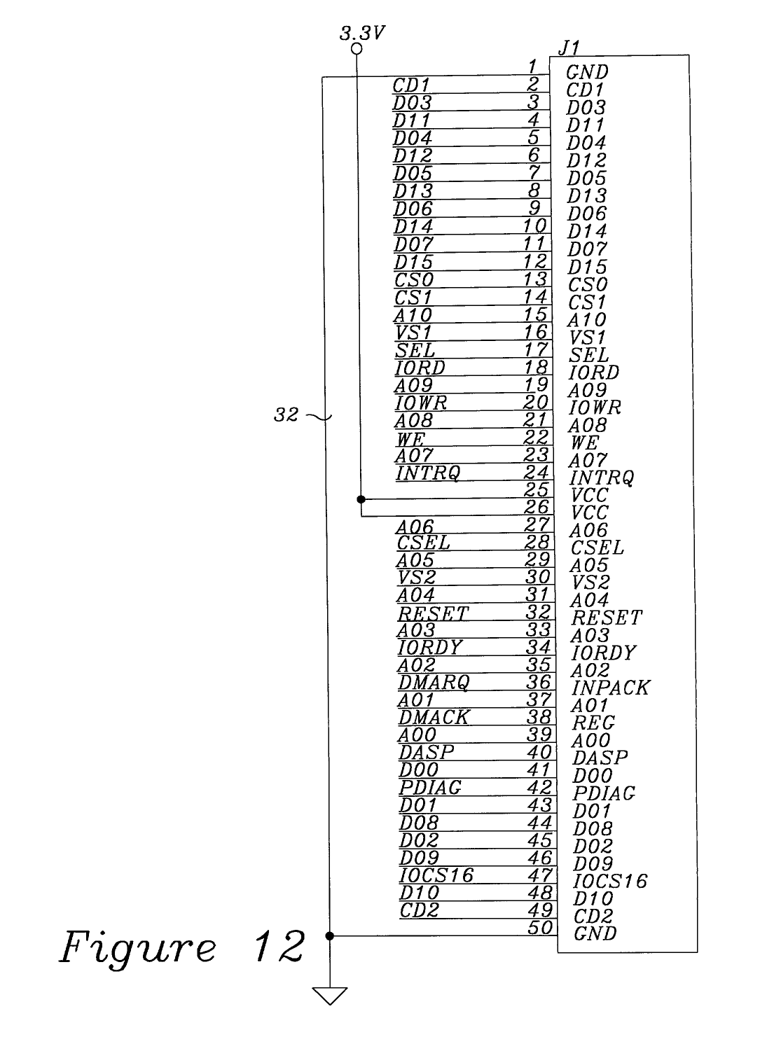

FIGS. 11 and 12 are a circuit schematics depicting pin location and a function for vibration isolating conductor 30 including drive socket 31, shown at FIG. 11, conductively connected to snap connector 32 shown at FIG. 12.

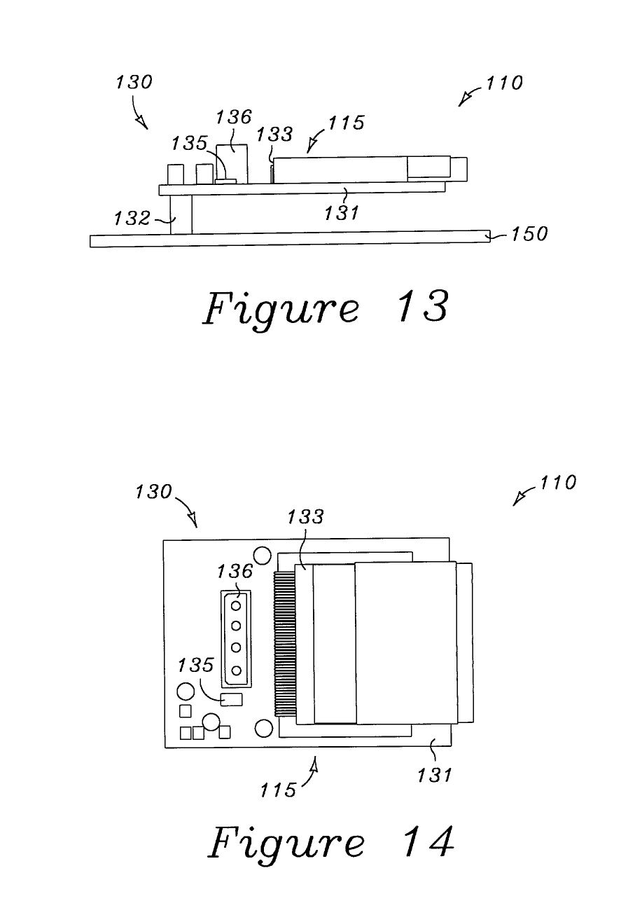

In the embodiment of the invention shown at FIGS. 13 through 17, micro hard drive caddy 110 includes frame 115 and drive mount adapter 130 for mounting micro hard drive M to a bus slot.

Referring to FIG. 13 and 16, drive mount adapter 130, includes bus connector 132 conductively connected to drive socket 133 through printed circuit board 131. In one embodiment, bus connector 132 is a 40 pin socket plug such as a Speedtech® B069-402201A6, 40 pin IDE connector. Bus connector 132 may be removably coupled to IDE connector 151 located on device substrate 150. While bus connector 132 is an IDE adapter plug, other bus architectures can be accommodated, such as a PCI bus. Also attached to printed circuit board 131 is drive socket 133. In one preferred embodiment, drive socket 133 is a Speedtech® N016-0100-004, which is a 50 pin 1.27 mm CF Type II reverse key receptacle.

Printed circuit board 131 provides a mechanical platform for supporting bus connector 132, drive socket 133, frame 115, micro hard drive M and associated electronics. In addition, printed circuit board 131 provides electrical connections or an interface circuit between various component parts of the micro hard drive caddy 110. In one embodiment of the invention, bus connector 132 and drive socket 133 are electrically connected, one to the other, by traces within printed circuit board 119. Drive mount adapter 134 is attached directly substrate 150 such as a motherboard. In one embodiment of the invention, drive mount adapter 134 includes voltage regulator 135. In one embodiment of the invention, voltage regulator 135 is a low dropout voltage regulator manufactured by National Semiconductor, part number LM1117mp-3.3V and conductively connected to printed circuit board 131. Power connector socket 136 as shown is a Molex® 15-24-4157 four pin power connector, generally compatible with personal computer power supply disk drive power cables.

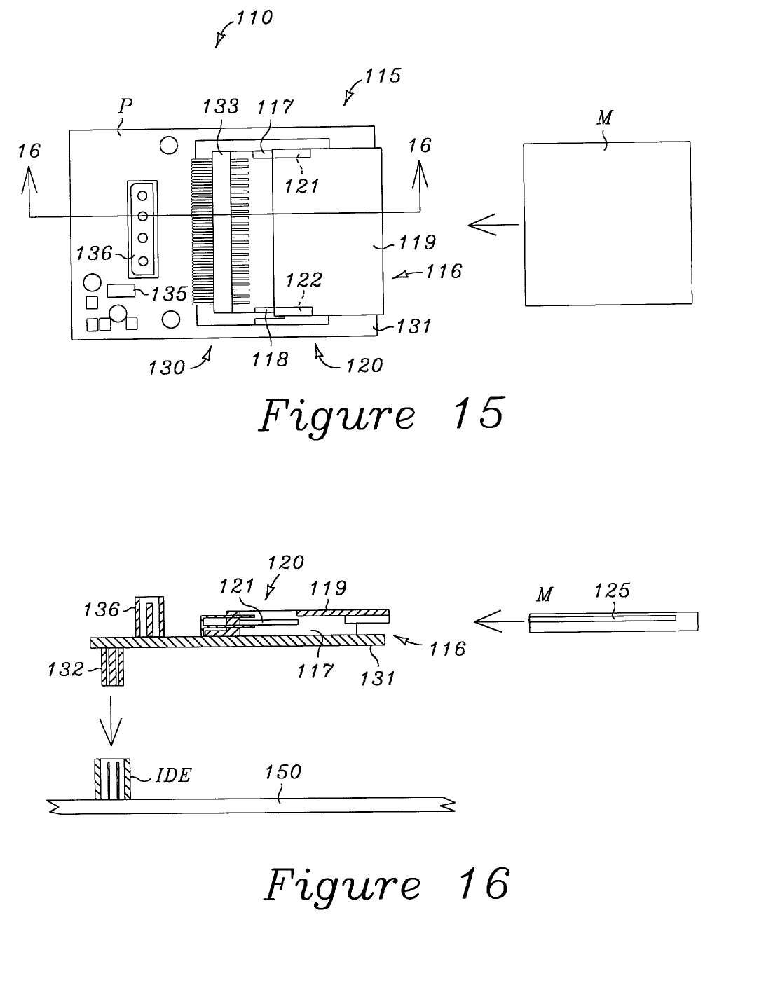

Referring to FIGS. 15 and 16, frame 115 includes retainer frame portion 116 and a disk support member 120 including first side member 117 and second side member 118 interconnected by spanning member 119. Disk support member 120 includes first support rail 121 formed on an inner surface of first side member 117 and second support rail 122 formed on an inner surface of second side member 118. First support rail 121 and second support rail 122 act as a slide engagement member and cooperate with first receiving channel (not shown) and second receiving channel 125 of micro hard drive M to facilitate the sliding engagement of micro hard drive M in frame 115 along the Y axis.

As seen in FIGS. 13 through 16, micro hard drive M fits within frame 115 with a sliding clearance between the outer surfaces of micro hard drive M and the corresponding inner faces of first side member 117, second side member 118, spanning member 119 and printed circuit board 131. Opposing inner faces of first side member 117 and second side member 118 serve together as an X axis movement limiter, limiting movement of micro hard drive M in an X axis. The opposing inner face of spanning member 119 and the upper surface of printed circuit board 131 serve together as a Y axis movement limiter, limiting movement of micro hard drive M in a Z axis. To the extent that movement is limited in the Y axis, such limitation is provided by the resistance to pull out provided by drive mount adapter 134.

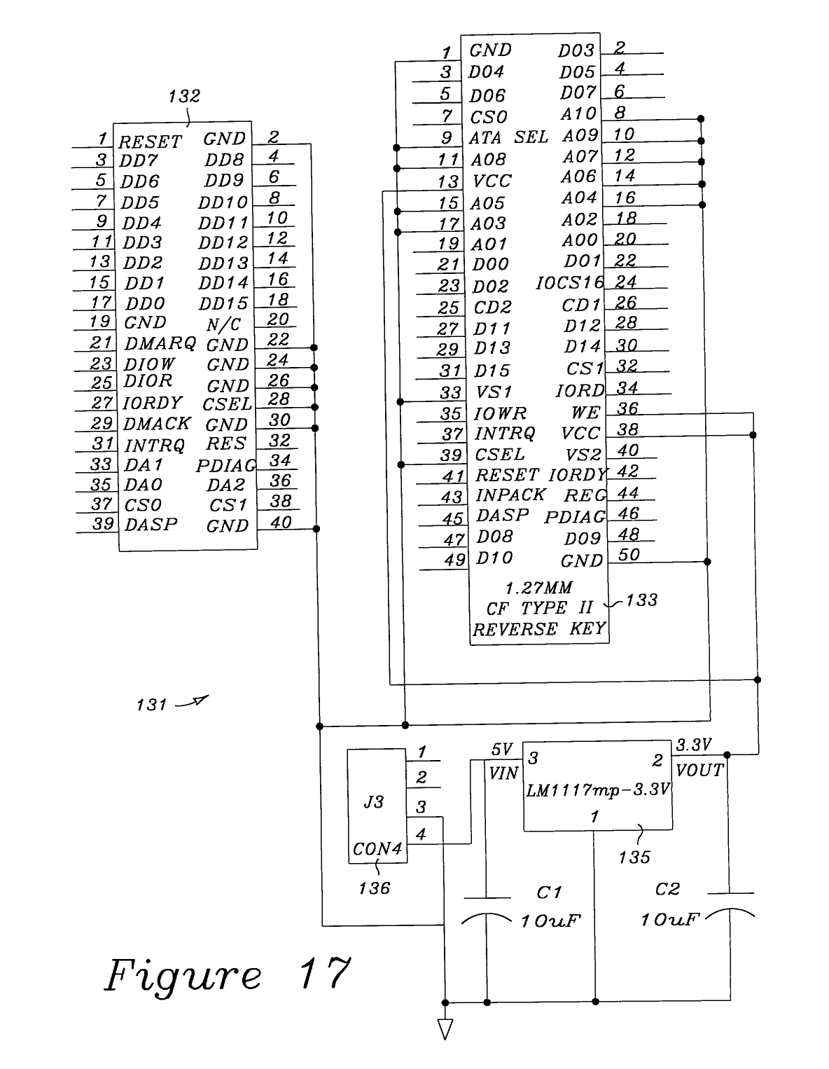

FIG. 17 shows a schematic depicting the circuit drive mount adapter 130 including bus connector 132, drive socket 133, voltage regulator 134 and four pin power connector 135. This particular schematic is configured to access the drive in IDE mode by setting inputs OE and CSEL active (low) and RESET high.

While this invention has been described with reference to the detailed embodiments, this is not meant to be construed in a limiting sense. Various modifications to the described embodiments, as well as additional embodiments of the invention, will be apparent to persons skilled in the art upon reference to this description. It is therefore contemplated that the appended claims will cover any such modifications or embodiments as fall within the true scope of the invention.

We claim:

1. A micro hard drive caddy comprising:
a micro hard drive frame connectable to an electronic device; and
a conductive connector for conductively connecting the micro hard drive to an electronic device.

2. The micro hard drive caddy of claim 1 wherein the frame further comprises:
a support frame portion; and
a retainer frame portion.

3. The micro hard drive caddy of claim 1 wherein the frame further comprises:
an X axis movement limiter including a first side frame member and an opposing second side frame member; and
a Y axis movement limiter including a spanning member, a first end of the spanning member connected to the first side frame member and a second end of the spanning member connected to the second side frame member.

4. The micro hard drive caddy of claim 1 wherein the frame further comprises:
an X axis movement limiter including a first side frame member and an opposing second side frame member;
a Y axis movement limiter including a spanning member, a first end of the spanning member connected to the first side frame member and a second end of the spanning member connected to the second side frame member; and
a Z axis movement limiter including a frame end member, a first end of the end member connected to the first side frame member and a second end of the end member connected to the second side frame member and an opposing face connected to the first side frame member.

5. The micro hard drive caddy of claim 1 wherein the frame further comprises a micro hard drive slide engagement member.

6. The micro hard drive caddy of claim 1 wherein the frame further comprises a soldering ear for soldered connection to the substrate.

7. The micro hard drive caddy of claim 1 wherein conductive connector for conductively connecting the micro hard drive to an electronic device further comprises:
a drive socket connected to the frame;
a conductor conductively connected to the drive socket; and
an adapter connector conductively connected to the conductor for conductive connection to a board mounted conductor.

8. The micro hard drive caddy of claim 1 wherein the adapter connector further comprises a bus interface socket conductively connected to the conductor.

9. The micro hard drive caddy of claim 1 wherein the adapter connector further comprises an integrated device electronics (IDE) ribbon cable connector conductively connected to the conductor.

10. The micro hard drive caddy of claim 1 wherein the adapter connector further comprises a Peripheral Component Interconnect (PCI) connector conductively connected to the conductor.

11. The micro hard drive caddy of claim 7 wherein the conductor further comprises a vibration isolating conductive ribbon.

12. The micro hard drive caddy of claim 7 wherein the conductor further comprises a printed circuit board.

13. The micro hard drive caddy of claim 1 further comprising a vibration isolation and dampening member including an elastomeric dampening member disposed between the frame and the micro hard drive.

14. The micro hard drive caddy of claim 1 further comprising a vibration isolation and dampening member including an elastomeric dampening member formed of a thermoplastic rubber disposed between an interior of the frame and an exterior surface of the micro hard drive.

15. The micro hard drive caddy of claim 1 further comprising a vibration isolation and dampening member including an elastomeric dampening member disposed between an interior of the frame and an exterior surface of the micro hard drive.

16. The micro hard drive caddy of claim 1 wherein the vibration isolation and dampening member further comprises an elastomeric support member disposed between an interior of the frame and an exterior surface of the micro hard drive within a footprint of the frame.

17. The micro hard drive caddy of claim 1 wherein the vibration isolation and dampening member further comprises an elastomeric support member disposed between an interior of the frame and an exterior surface of the micro hard drive within a footprint of the frame
